(19) United States
(12) Patent Application Publication
(10) Pub. No.: US 2025/0275446 A1
(43) Pub. Date: Aug. 28, 2025

(54) DISPLAY DEVICE AND METHOD FOR MANUFACTURING THE SAME

(71) Applicant: Samsung Display Co., LTD., Yongin-si (KR)

(72) Inventors: HYUNKYUNG YUN, Yongin-si (KR); SANGDUK LEE, Yongin-si (KR)

(21) Appl. No.: 19/059,863

(22) Filed: Feb. 21, 2025

(30) Foreign Application Priority Data
Feb. 23, 2024 (KR) 10-2024-0026419

(51) Int. Cl. H10K 59/80; H10K 59/12

(52) U.S. Cl. CPC H10K 59/8791; H10K 59/1201; H10K 59/873

(57) ABSTRACT

A display device includes a display module, a light control layer disposed on the display module, and a coating window disposed directly on an upper surface of the light control layer and formed from a window resin including a polymer resin, a photoinitiator, and a photosensitizer. A content of each of the photoinitiator and the photosensitizer included in the coating window is less than about 10,000 atomic mass unit, and the content is measured through gas chromatography-mass spectrometry, and thus the display device may maintain excellent optical properties to exhibit improved reliability.

This application claims priority to Korean Patent Application No. 10-2024-0026419, filed on Feb. 23, 2024, and all the benefits accruing therefrom under 35 U.S.C. § 119, the content of which in its entirety is herein incorporated by reference.

### BACKGROUND

### 1. Field

The disclosure herein relates to a display device including a coating window and a method for manufacturing the same.

### 2. Description of the Related Art

Various display devices used for multimedia devices such as a television, a mobile phone, a tablet computer, and a game console are being developed. A display device may include a display panel which generates images, and a window member for protecting the display panel. The window member, which is disposed on an uppermost part of the display device, should maintain reliability in consideration of a usage environment of the display device.

### SUMMARY

The disclosure provides a display device with excellent reliability even when exposed to an external light source, etc., and a method for manufacturing the same.

Additionally, the disclosure also provides a display device with improved reliability by easily removing unreacted compounds from a coating window without damage to a display module, and a method for manufacturing the same.

An embodiment of the inventive concept provides a display device including: a display module; a light control layer disposed on the display module; and a coating window disposed directly on an upper surface of the light control layer and formed from a window resin including a polymer resin, a photoinitiator, and a photosensitizer, wherein a content of each of the photoinitiator and the photosensitizer included in the coating window is less than about 10,000 atomic mass unit (amu), and the content is measured through gas chromatography-mass spectrometry (“GC-MS”).

In an embodiment, the polymer resin may include a silsesquioxane resin.

In an embodiment, the photoinitiator may be an iodonium salt, and the photosensitizer may be isopropylthioxanthone (“ITX”).

In an embodiment, the coating window may have a thickness of about 600 micrometers (μm) or more.

In an embodiment, the coating window may have a light transmittance of about 30% or more in a wavelength range of about 750 nanometers (nm) to about 1000 nm.

In an embodiment, the coating window may have, in a visible light range, a transmittance of about 90% or more and a yellow index of about 1 or less.

In an embodiment, the coating window may be a single layer.

In an embodiment, the display device may further include a printed layer disposed directly between the light control layer and the coating window, wherein the printed layer may include a portion non-overlapping the display module.

In an embodiment, the coating window may overlap the entirety of the display module, and in a plan view, an area of the coating window may be greater than an area of an upper surface of the display module.

In an embodiment, the light control layer may be a polarization layer, and an edge of the polarization layer may overlap an edge of the coating window.

In an embodiment of the inventive concept, a method for manufacturing a display device includes: providing a display module; providing a light control layer on the display module; forming a coating window directly on an upper surface of the light control layer; and providing near infrared rays to the coating window.

In an embodiment, the forming the coating window may include: providing directly, on the upper surface of the light control layer, a window resin including a polymer resin, a photoinitiator, and a photosensitizer; and curing the provided window resin using ultraviolet rays.

In an embodiment, a content of each of the photoinitiator and the photosensitizer, after the providing the near infrared rays, may be less than about 10,000 amu, and the content may be measured through GC-MS.

In an embodiment, the providing the near infrared rays may include removing the photoinitiator and the photosensitizer remaining in the coating window after the curing the window resin.

In an embodiment, the photoinitiator may be an iodonium salt, and the photosensitizer is ITX.

In an embodiment, the polymer resin may include a silsesquioxane resin.

In an embodiment, the coating window, after the curing the window resin, may have a curing rate of about 90% or more.

In an embodiment, a process temperature in the providing the near infrared rays may be about 40 degrees Celsius (° C.) or more to about 80° C. or less.

In an embodiment, the coating window may have a light transmittance of about 30% or more in a wavelength range of about 750 nm to about 1000 nm.

In an embodiment, in the forming the coating window, an edge of the coating window may overlap an edge of the light control layer, and the edge of the light control layer may further protrude outwards than an edge of the display module.

### BRIEF DESCRIPTION OF THE DRAWINGS

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a perspective view of an embodiment of a display device;

FIG. 2 is an exploded perspective view of an embodiment of a display device;

FIG. 3 is a cross-sectional view of a display device of an embodiment, illustrating a part taken along line I-I′ of FIG. 2;

FIG. 4 is a plan view illustrating a display device of an embodiment;

FIG. 5 is a flowchart showing a method for manufacturing a display device of an embodiment;

FIGS. 6A to 6E are respectively schematic views illustrating operations of a method for manufacturing a display device of an embodiment; and

FIG. 7 is a cross-sectional view illustrating an operation of a method for manufacturing a display device of an embodiment.

FIG. 8 is a block diagram illustrating an electronic device according to an embodiment.

### DETAILED DESCRIPTION

The inventive concept may be implemented in various modifications and have various forms, and illustrative embodiments are illustrated in the drawings and described in detail in the text. It is to be understood, however, that the inventive concept is not intended to be limited to the particular forms disclosed, but on the contrary, is intended to cover all modifications, equivalents, and alternatives falling within the spirit and scope of the inventive concept.

In this specification, it will be understood that when an element (or region, layer, portion, or the like) is referred to as being “on”, “connected to” or “coupled to” another element, it may be directly disposed/connected/coupled to another element, or intervening elements may be disposed therebetween.

Like reference numerals or symbols refer to like elements throughout. Also, in the drawings, the thicknesses, the ratios, and the dimensions of the elements are exaggerated for effective description of the technical contents. The term “and/or” includes all combinations of one or more of the associated listed elements.

Although the terms first, second, etc., may be used to describe various elements, these elements should not be limited by these terms. These terms are only used to distinguish one element from another element. For example, a first element may be referred to as a second element, and similarly, a second element may also be referred to as a first element without departing from the scope of the inventive concept. The singular forms include the plural forms as well, unless the context clearly indicates otherwise.

Also, the terms such as “below”, “lower”, “above”, “upper” and the like, may be used for the description to describe one element's relationship to another element illustrated in the drawing figures. It will be understood that the terms have a relative concept and are described on the basis of the orientation depicted in the drawing figures.

It will be understood that the term “includes” or “comprises”, when used in this specification, specifies the presence of stated features, integers, steps, operations, elements, components, or a combination thereof, but does not preclude the presence or addition of one or more other features, integers, steps, operations, elements, components, or combinations thereof.

In this specification, it will be understood that “being directly disposed” means that there are no intervening layers, films, regions, plates, or the like between a portion of layers, films, regions, plates, or the like and another portion. For example, “being directly disposed” may mean to be disposed between two layers or two members without using an additional member such as an adhesive member or like.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term “about” can mean within one or more standard deviations, or within +30%, 20%, 10%, 5% of the stated value, for example.

Unless otherwise defined, all terms (including technical and scientific terms) used herein have the same meaning as commonly understood by one of ordinary skill in the art to which the disclosure belongs. Also, terms, such as those defined in commonly used dictionaries, should be interpreted as having a meaning that is consistent with their meaning in the context of the relevant art and should not be interpreted in an idealized or overly formal sense unless expressly so defined herein.

Hereinafter, a display device of an embodiment and a method for manufacturing the same will be described with reference to the accompanying drawings.

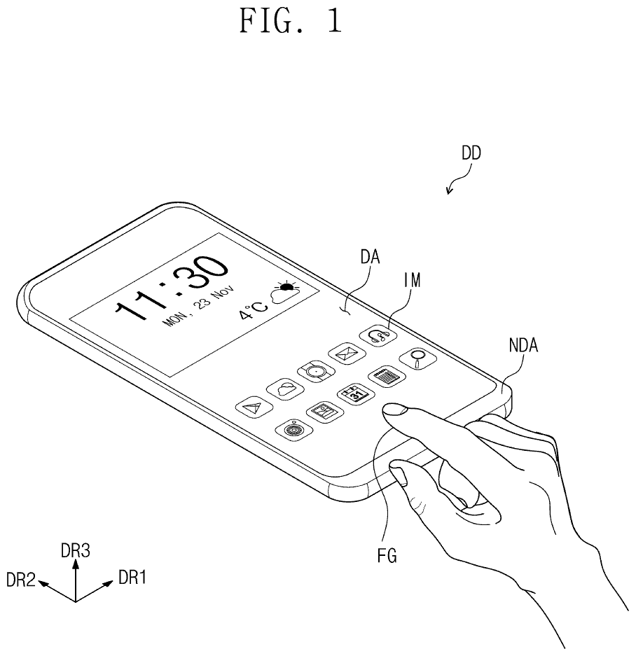

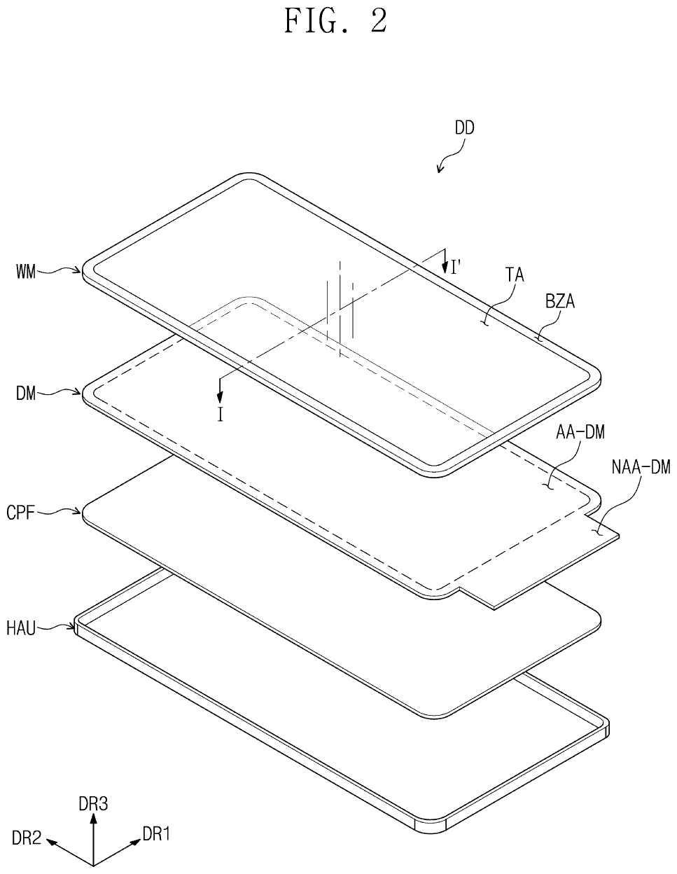

FIG. 1 is a perspective view illustrating an embodiment of a display device. FIG. 2 is an exploded perspective view of an embodiment of a display device.

Referring to FIG. 1, a display device DD may be activated in response to an electrical signal and display images. In an embodiment, the display device DD may be a personal computer (“PC”), a laptop computer, a personal digital terminal, a game console, a portable electronic device, a television, a monitor, an outdoor billboard, a car navigation unit, or a wearable device, for example, but the inventive concept is not limited thereto. In FIG. 1, the display device DD is illustrated as a mobile phone.

The display device DD may be rigid or flexible. The wording “flexible” means having a bendable property. In an embodiment, the flexible display device DD may include a curved device, a rollable device, or a foldable device, for example.

In FIG. 1 and the following drawings, a first direction axis DR1 to a third direction axis DR1, DR2, DR3 are illustrated, and directions indicated by the first to third direction axes DR1, DR2, and DR3 described herein may have a relative concept and may thus be changed to other directions. In addition, the directions indicated by the first to third direction axes DR1, DR2, and DR3 may be also referred to as first to third directions DR1, DR2, and DR3, and may be denoted as the same reference numerals or symbols. In this specification, the first direction axis DR1 and the second direction axis DR2 may be orthogonal to each other, and the third direction axis DR3 may be a normal direction of a plane defined by the first direction axis DR1 and the second direction axis DR2.

A thickness direction of the display device DD may be parallel to the third direction axis DR3 which is the normal direction of the plane defined by the first direction axis DR1 and the second direction axis DR2. The display device DD may display an image IM through a display surface. In this specification, a front surface (or upper surface) and a rear surface (or lower surface) of each component are defined based on a direction in which the image IM is displayed.

In this specification, the wording “in a plan view” may be defined as a state when viewed in the third direction DR3. In this specification, the wording “in a cross-section” may be defined as a state when viewed in the first direction DR1 or the second direction DR2. The directions indicated by the first to third directions DR1 to DR3 have a relative concept, and may thus be changed to other directions.

The display device DD in an embodiment may display the image IM through a display region DA. The display region DA may include a flat surface defined by the first direction DR1 and the second direction DR2. The display region DA may include a curved surface bent from at least one side of the flat surface defined by the first direction DR1 and the second direction DR2. A surface, on which the image IM is displayed, may correspond to a front surface of the display device DD. The image IM may include not only a dynamic image but also a static image.

A non-display region NDA is next (adjacent) to the display region DA. The non-display region NDA may surround the display region DA. Accordingly, a shape of the display region DA may be substantially defined by the non-display region NDA. However, this is illustrated. The non-display region NDA may be next (adjacent) to only one side of the display region DA or may be omitted. The display device DD in an embodiment of the inventive concept may include a display region having various shapes, but is not limited to a particular embodiment.

On a plane, the display device DD may have a quadrangular shape, e.g., rectangular shape which has short sides extending in the first direction DR1 and long sides extending in the second direction DR2 crossing the first direction DR1. However, the inventive concept is not limited thereto, and in a plan view, the display device DD may have various shapes, such as a circular or polygonal shape.

Although not illustrated, the display device DD of an embodiment may be a flexible display device. At least a partial region of the display device DD of an embodiment may be bent and deformed. In an alternative embodiment, the display device DD of an embodiment may be a foldable device which is variably deformed into a folded state and a non-folded state with respect to at least one folding axis extending in one direction.

The display device DD of an embodiment may detect an external input applied from the outside. The external input may include various types of inputs such as force, pressure, temperature, and light. The display device DD of an embodiment may detect an external input (e.g., user's touch input) FG applied from the outside. The external input FG includes various types of external inputs such as a part of a user's body, light, heat, or pressure. In this embodiment, it is illustrated that the user's input is a user's hand exerted on a front surface. However, this is illustrated, and as described above, the external input FG may be provided in various forms. Additionally, the display device DD may detect the user's input which is applied to a side surface or a rear surface of the display device DD according to a structure, and is not limited to a particular embodiment.

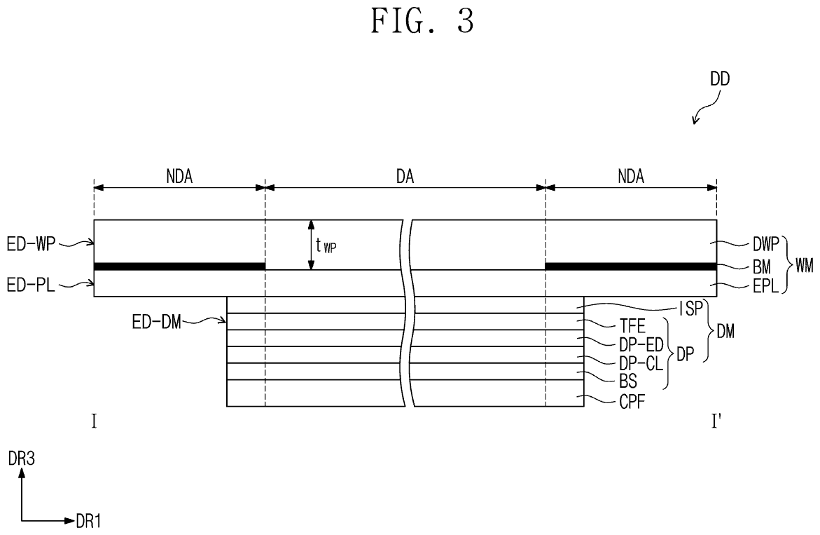

The display device DD of an embodiment includes a display module DM. The display module DM may be a component which generates an image and detects an input applied from the outside. The display module DM in an embodiment may include a display panel DP (refer to FIG. 3) and an input sensor ISP (refer to FIG. 3) disposed on the display panel DP.

The display device DD of an embodiment may include a window member WM disposed on an upper part of the display module DM. The display device DD may further include a support member CPF and a housing HAU, which are disposed below the display module DM.

In the display device DD illustrated in FIGS. 1 and 2, the window member WM and the housing HAU may be coupled to constitute the exterior of the display device DD. The housing HAU may include a material having relatively high rigidity. In an embodiment, the housing HAU may include a plurality of frames and/or plates composed of glass, plastic, or metal, for example. The housing HAU may provide a predetermined accommodation space. The display module DM may be accommodated inside the accommodation space and protected against an external impact.

An active region AA-DM and a peripheral region NAA-DM may be defined in the display module DM. The active region AA-DM may be activated in response to an electrical signal. The peripheral region NAA-DM may be disposed next (adjacent) to at least one side of the active region AA-DM. A driving circuit, a driving line, or the like for driving the active region AA-DM may be disposed in the peripheral region NAA-DM.

The active region AA-DM may correspond to the display region DA of the display device illustrated in FIG. 1. The peripheral region NAA-DM may be disposed to surround the active region AA-DM. However, the inventive concept is not limited thereto, and unlike what is illustrated in FIG. 2, etc., a portion of the peripheral region NAA-DM may be omitted in an embodiment. The peripheral region NAA-DM may correspond to the non-display region NDA of the display device illustrated in FIG. 1.

The window member WM may be disposed on the display module DM and protect the display module DM against external impacts or scratches. The window member WM may cover the entirety of the exterior of the display module DM. A front surface of the window member WM may correspond to an upper surface of the display device DD described above.

The window member WM may be divided into a transmission part TA and a bezel part BZA. The transmission part TA may correspond to the active region AA-DM of the display module DM, and the bezel part BZA may correspond to the peripheral region NAA-DM of the display module DM. The bezel part BZA may define a shape of the transmission part TA. The bezel part BZA may be next (adjacent) to the transmission part TA and surround the transmission part TA. However, an embodiment of the inventive concept is not limited to what is illustrated in the drawings, and the bezel part BZA may be disposed next (adjacent) to only one side of the transmission part TA, or a portion thereof may be omitted.

The support member CPF may be a layer which is disposed below the display module DM to protect a rear surface of the display module DM. The support member CPF may overlap the entirety of the display module DM. The support member CPF may include a polymer material. In an embodiment, the support member CPF may be a polyimide film or a polyethylene terephthalate film, for example. However, this is presented in an embodiment, and a material of the support member CPF is not limited thereto. The support member CPF may further include a thickness compensation layer which is disposed below the display module DM to compensate for a thickness, or a buffer layer for improving the durability of the display device.

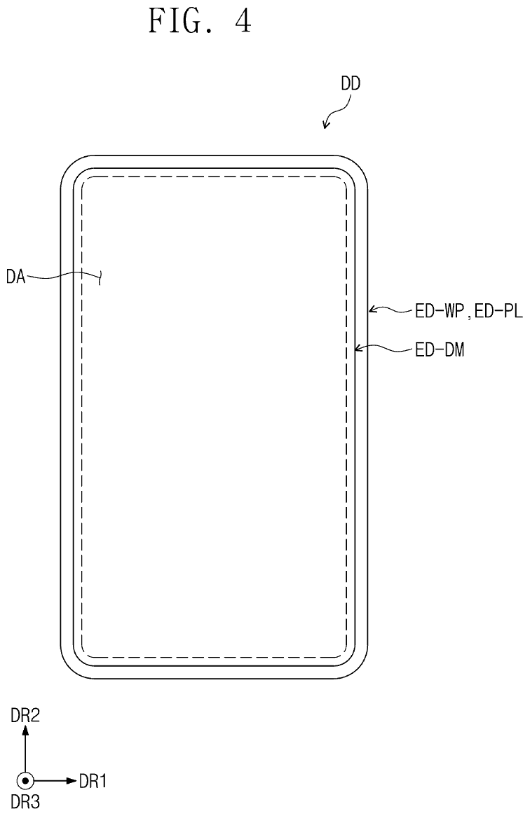

FIG. 3 is a cross-sectional view of a display device. FIG. 3 is a cross-sectional view taken along line I-I′ of FIG. 2, and for ease of description, the housing HAU is omitted. FIG. 4 is a plane view of a display device of an embodiment. FIG. 4 schematically illustrates the display device in a plan view defined by the first direction DR1 and the second direction DR2. FIG. 4 briefly illustrates a plan view of the display device in consideration of an arrangement relationship between edges of a window member and a display module.

Referring to FIG. 3, a display module DM may include a display panel DP and an input sensor ISP disposed on the display panel DP.

The display panel DP may substantially generate an image. The display panel DP may be a light-emitting display panel. In an embodiment, the display panel DP may be an organic light-emitting display panel, an inorganic light-emitting display panel, a quantum dot display panel, a micro light-emitting diode (“LED”) display panel, or a nano LED display panel, for example. The display panel DP may be also referred to as a display layer. In an embodiment, the display panel DP may include a base layer BS, a circuit layer DP-CL, a display element layer DP-ED, and an encapsulation layer TFE.

The base layer BS may be a member that provides a base surface on which the circuit layer DP-CL is disposed. The base layer BS may be a rigid substrate or a flexible substrate which is bendable, foldable, rollable, or the like. The base layer BS may be a glass substrate, a metal substrate, a polymer substrate, or like. However, the inventive concept is not limited thereto, and the base layer BS may be an inorganic layer, an organic layer, or a composite material layer.

The circuit layer DP-CL may be disposed on the base layer BS. The circuit layer DP-CL may include a plurality of insulating layers, a plurality of transistors, a conductive pattern, a signal line, or the like. In an embodiment, a plurality of inorganic films, a plurality of organic films, a semiconductor layer, and a conductive layer may be formed through coating, deposition, or the like. Thereafter, the inorganic films, the organic films, the semiconductor layer, and the conductive layer may be selectively patterned by performing a photolithography process. In this manner, the circuit layer DP-CL including a plurality of insulating layers each formed from inorganic films and organic films, transistors including a semiconductor pattern formed from the semiconductor layer, and a conductive pattern and a signal line formed from the conductive layer, etc., may be formed. In FIG. 3, a configuration of the circuit layer DP-CL is briefly illustrated, and the transistors and signal lines, etc., of the circuit layer DP-CL may be electrically connected to a display element included in a display element layer DP-ED.

The display element layer DP-ED may be formed on the circuit layer DP-CL. The display element layer DP-ED may include a display element. In an embodiment, the display element may include a first electrode and a second electrode facing each other, and a light-emitting layer which is disposed between the first electrode and the second electrode and includes a light-emitting material, for example.

The display panel DP may include an encapsulation layer TFE covering the display element layer DP-ED. The encapsulation layer TFE may protect the display element layer DP-ED against moisture, oxygen, and foreign substances such as dust particles. The encapsulation layer TFE may include at least one inorganic layer. In an embodiment, the encapsulation layer TFE may include an inorganic layer, an organic layer, and an inorganic layer which are sequentially stacked, for example.

The input sensor ISP may be disposed on the encapsulation layer TFE. In an embodiment, the input sensor ISP may include insulating layers and a sensor conductive layer. In an embodiment, the input sensor ISP may be directly disposed on the encapsulation layer TFE. The input sensor ISP may detect an external input, change the detected external input to a predetermined input signal, and provide the input signal to the display panel DP. In an embodiment, the input sensor ISP may be a touch-sensing layer which detects a touch, for example. The input sensor ISP may recognize a direct touch by a user, an indirect touch by a user, a direct touch by an object, an indirect touch by an object, or the like.

The input sensor ISP may detect at least one of a position or intensity (pressure) of a touch applied from the outside. The input sensor ISP may have various structures or consist of various materials, but is not limited to a particular embodiment. In an embodiment, the input sensor ISP may detect an external input in a capacitive manner, for example. The display panel DP may receive input signals from the input sensor ISP and generate images corresponding to the input signals.

In an embodiment, the window member WM may include a light control layer EPL and a coating window DWP disposed on the light control layer EPL. The coating window DWP may be directly disposed on the light control layer EPL. The coating window DWP may be formed by coating and curing a window resin including an organic material.

The light control layer EPL may be a reflection reduction layer which reduces external light reflectance for light incident from the outside of the display device DD. However, the inventive concept is not limited thereto, and the light control layer EPL may include various light functional layers for improving the display quality of the display device DD. In an embodiment, the light control layer EPL of an embodiment may be a polarizing layer, for example. However, the inventive concept is not limited thereto, and in an embodiment, the light control layer EPL may include a destructive interference structure, a plurality of color filters, or the like.

The light control layer EPL may be disposed on the display module DM. The light control layer EPL may reduce reflectance for external light incident from the outside of the display device DD to the display module DM. In an embodiment, the light control layer EPL may be a polarization layer, and the polarization layer may further include an optical functional layer such as a retarder in addition to a polarizer, and functional layers for supporting and protecting the polarizer.

In an embodiment, the light control layer EPL may be provided in a film form. In an embodiment, the light control layer EPL may include a stacked structure of functional layers, such as a film layer serving as a base substrate, a polarizer disposed on the film layer, and a protective film disposed on the polarizer. In an embodiment, an adhesive layer may be further disposed between the light control layer EPL, provided in a film form, and the display module DM, for example.

The light control layer EPL may be disposed to cover the entirety of the display module DM. The light control layer EPL may be provided in a film form, and function as a support layer on which the coating window DWP is disposed. That is, in the display device DD of an embodiment, the light control layer EPL may serve as a base substrate on which a window resin is provided when forming the coating window DWP through a coating process.

The window member WM may further include a printed layer BM. The printed layer BM may be disposed on an upper surface of the light control layer EPL. The printed layer BM may have a predetermined color. The printed layer BM may correspond to the non-display region NDA. The printed layer BM may be disposed to correspond to the peripheral region NAA-DM (refer to FIG. 2) and prevent components, of the peripheral region NAA-DM, from being viewed from the outside. The printed layer BM may define a bezel part BZA.

In an embodiment, the coating window DWP may be formed from a window resin including a polymer resin, a photoinitiator, and a photosensitizer. The window resin from which the coating window DWP is formed may be an optically transparent insulating material. In an embodiment, the polymer resin may include a base resin such as a silicone-based resin, a polyurethane-based resin, a urethane acrylate-based resin, a polyurea-based resin, an epoxy-based resin, or the like. In an embodiment, the polymer resin may include a thermosetting base resin, for example. A type of base resin included in the window resin is not limited to what is described above. The base resin is not particularly limited and is an insulating material having an optically transparent property. Any base resin may be used without a limitation as long as capable of forming a layer having a predetermined thickness through a coating process. The “base resin” may mean a resin which is a major component among materials included in the window resin from which the coating window DWP is formed.

In an embodiment, the polymer resin may include two or more base resins, and the two or more base resins may include the same based-resin. In this case, the base resins may differ from each other in terms of a predetermined structure such as a side chain structure. When the two or more base resins include the same based-resin as each other, there is an advantage in that mixing may be easily performed. However, the inventive concept is not limited thereto.

In an embodiment, the polymer resin may include a silsesquioxane resin. In an embodiment, the polymer resin may include an epoxy-based silsesquioxane resin, for example.

The window resin may include a photoinitiator. The photoinitiator may be activated in response to ultraviolet light. The photoinitiator included in the window resin in an embodiment has mobility increased due to near infrared rays, and may thus be volatilized and removed. In an embodiment, the photoinitiator may include an iodonium salt, for example. The iodonium salt may be easily extracted and removed from the coating window when near infrared rays are provided.

The window resin may include a photosensitizer. The photosensitizer may accelerate the activity of the photoinitiator. The window resin includes both a photoinitiator and a photosensitizer, and may thus have an increased photocuring efficiency. The photosensitizer included in the window resin in an embodiment has mobility increased due to near infrared rays, and may thus be volatilized and removed. In an embodiment, the photosensitizer may include isopropylthioxanthone (“ITX”), for example. The ITX may be easily extracted and removed from the coating window when near infrared rays are provided.

That is, the photoinitiator and the photosensitizer included in the window resin of an embodiment may be easily volatilized and removed due to near infrared rays. When near infrared rays are provided, the photoinitiator and the photosensitizer included in the window resin of the coating window DWP may be sufficiently removed at a temperature of about 40 degrees Celsius (° C.) or more to about 80° C. or less.

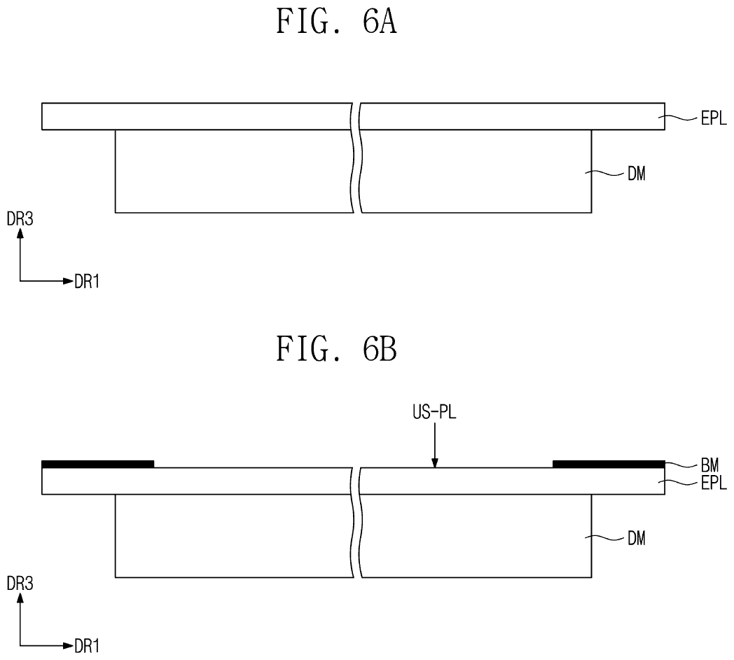

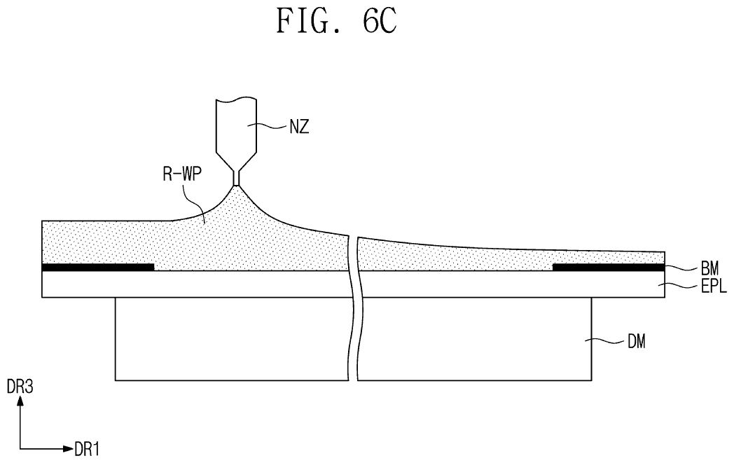

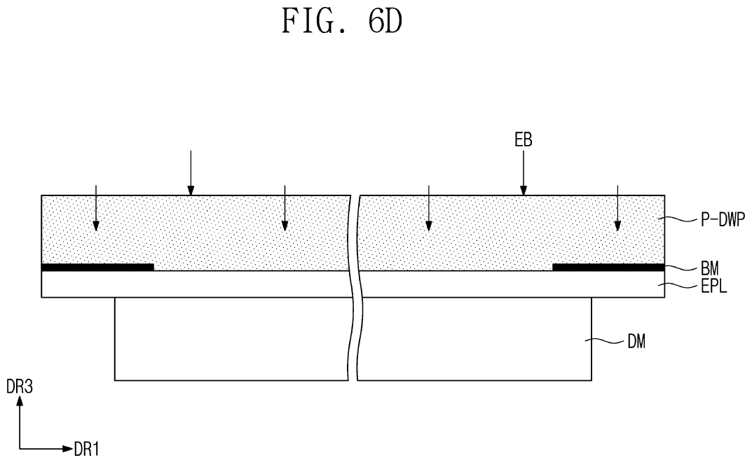

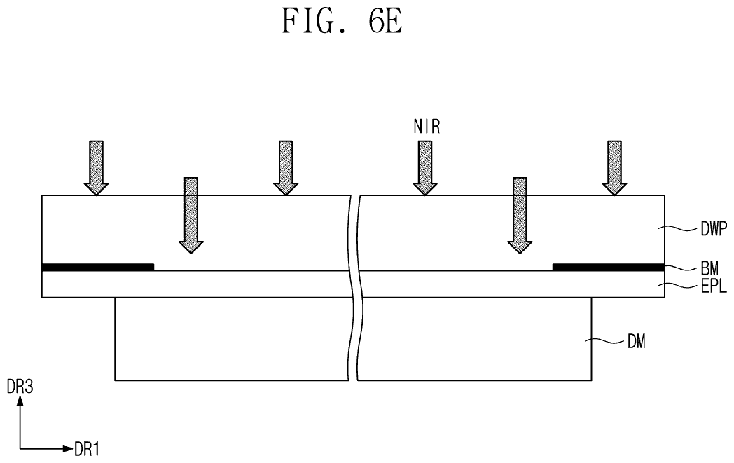

In a method for manufacturing a display device of an embodiment to be described later, the coating window DWP of an embodiment may be formed by providing a window resin R-WP (FIG. 6C). The coating window DWP is not provided as a separate member and may be formed through direct coating of the light control layer EPL. The coating window DWP may not include an additional substrate such as a glass substrate or a plastic substrate. The coating window DWP may be a coating layer formed from a window resin, and in an embodiment, the coating window DWP may be a single layer.

A typical display device is manufactured by providing, on a display module, a window including a glass substrate during a separate process. The window including the glass substrate is attached to the display module through a lamination process, and an adhesive member, etc., for attaching the window is desired. In the coating window DWP formed by directly providing the window resin R-WP (refer to FIG. 6C), a glass substrate, an adhesive member, etc., may be excluded, thereby reducing manufacturing costs. A cut out process and an attachment process for window lamination may be excluded, and thus the coating window DWP may be manufactured through a process with improved manufacturing efficiency.

In the coating window DWP in an embodiment, the photoinitiator and the photosensitizer may be each contained only in an amount of less than about 10,000 atomic mass unit (amu). The coating window DWP in an embodiment may include only substantially small amounts of the photoinitiator and the photosensitizer. In an embodiment, the coating window DWP in an embodiment may not include an unreacted photoinitiator and an unreacted photosensitizer, for example.

The coating window DWP in an embodiment includes or consists of the photoinitiator and the photosensitizer only each in an amount of less than about 10,000 amu, and therefore, even when the coating window DWP is exposed to external light, reaction caused by activation of the photoinitiator and the photosensitizer does not occur, or photoreaction may occur minimally, thereby minimizing deformation of the organic material that forms the coating window DWP. That is, the display device DD of an embodiment includes the coating window DWP including or consisting of the photoinitiator and the photosensitizer each in an amount of less than about 10,000 amu. Accordingly, even under the condition that the photoinitiator and the photosensitizer are activated, when exposed to external light, for example, the coating window DWP maintains not only the optical property but also the mechanical property, and thus the display device DD may exhibit excellent reliability.

In this specification, contents of the photoinitiator and the photosensitizer were measured through gas chromatography-mass spectrometry (“GC-MS”). The contents of the photoinitiator and the photosensitizer were evaluated based on the content at a predetermined peak in which a component of each of the photoinitiator and the photosensitizer may be identified.

In an embodiment, the coating window DWP may have a thickness t_{WP} of about 600 micrometers (μm) or more. The coating window DWP is provided to have a thickness of about 600 μm or more, and may thus sufficiently protect, above the display module DM, the display module DM. Additionally, even though the coating window DWP of an embodiment is provided to have a sufficient thickness of about 600 μm or more, the coating window DWP includes or consists of the photoinitiator and the photosensitizer only each in an amount of less than about 10,000 amu, and thus may exhibit the excellent optical property without deformation even when exposed to external light.

The coating window DWP in an embodiment may have a transmittance of about 90% or more in a visible light range, and have a yellow index of about 1 or less. The yellow index may be measured through an ASTM E313 method. Since the coating window DWP, in an embodiment, formed by directly coating a window resin has relatively high light transmittance in a visible light range and a relatively low yellow index property, the coating window DWP may replace a glass substrate, thereby making it possible for the display device DD to display the excellent display quality.

The coating window DWP in an embodiment may have transmittance of about 30% or more in an infrared light region. In an embodiment, in the display device DD of an embodiment, the coating window DWP may have a light transmittance of about 30% or more in a wavelength range of about 750 nanometers (nm) to about 1000 nm, for example. Since the coating window DWP has a light transmittance of about 30% or more in a wavelength range of about 750 nm to about 1000 nm, near infrared rays may reach the entirety of the region of the coating window DWP when the near infrared rays are provided on the coating window DWP. Accordingly, an unreacted photoinitiator, an unreacted photosensitizer, other reaction residues, etc., included in the coating window DWP may be easily removed when near infrared rays are provided.

The coating window DWP of an embodiment may be disposed to cover an entirety of the display module DM. Referring to FIGS. 3 and 4, the coating window DWP overlaps an entirety of the display module DM, and in a plan view, the area of the coating window DWP may be greater than the area of an upper surface of the display module DM. Also, the light control layer EPL overlaps the entirety of the display module DM, and in a plan view, the area of the light control layer EPL may be greater than the area of the upper surface of the display module DM.

In an embodiment, an edge ED-PL of the light control layer EPL may overlap an edge ED-WP of the coating window DWP. In an embodiment, the light control layer EPL is a layer serving as a base substrate on which the coating window DWP is disposed, and the coating window DWP may be provided to have an area corresponding to the light control layer EPL. A window resin may be coated on the light control layer EPL and thus be provided so as to correspond to an upper surface of the light control layer EPL. An edge ED-WP of the coating window DWP formed from the window resin thus provided may overlap an edge ED-PL of the light control layer EPL. In an embodiment, the light control layer EPL may be a polarization layer, and the edge ED-PL of the polarization layer may overlap the edge ED-WP of the coating window, for example.

In the display device DD of an embodiment, the edge ED-DM of the display module DM may be disposed further inward than an edge of the window member. In an embodiment, the edge ED-DM of the display module DM may be disposed more adjacent (closer) to the display region DA than each of the edge ED-WP of the coating window DWP and the edge ED-PL of the light control layer EPL is to the display region DA.

In an embodiment, the printed layer BM may be directly disposed between the light control layer EPL and the coating window DWP. The coating window DWP may be disposed to cover a stepped portion of the printed layer BM. The printed layer BM may be formed by coating and curing an ink resin or the like on the light control layer EPL. The printed layer BM may correspond to the non-display region NDA. The printed layer BM may include a portion non-overlapping the display module DM, and a portion of the printed layer BM may overlap the display module DM.

The coating window DWP in an embodiment may be provided to be directly coated on the light control layer EPL, and to have a sufficient thickness, thereby ensuring excellent mechanical property for protecting the display module DM. Additionally, the coating window DWP in an embodiment includes or consists of a photoinitiator and a photosensitizer only each in an amount of less than about 10,000 amu, and may thus exhibit excellent reliability. The coating window DWP in an embodiment includes or consists of the photoinitiator and the photosensitizer only each in an amount of less than about 10,000 amu, and thus it is possible to minimize deformation, of the coating window, caused by additional light reaction when the display device is exposed to external light.

In the display device of an embodiment, the amount of change in a yellow index in the exposure environment test below may be about 3 or less.

The exposure environment test was performed by blocking a partial region of the display device from light, dividing into a light-blocking portion and an exposed portion, placing the display device in a non-driving state in a chamber, and repeating the following cycle 10 times. One cycle below is performed for about 24 hours.

A temperature was raised from about 25° C. to about 40° C. (a temperature at an upper part of the display device was set to be about 40° C.) for about 6 hours, maintained at the raised temperature for about 4 hours, and a test light source emitted light for about 8 hours after about 2 hours from a time when the temperature started to be raised. The test light source was blocked for the remaining 16 hours out of about 24 hours. Afterwards, the temperature was lowered from about 40° C. to about 25° C. for about 10 hours and maintained at about 25° C. for about 4 hours.

The light source characteristics of the test light source (solar lamp) are shown below in Table 1.

TABLE 1

| Spectrum | | | | Irradiance |
|---|---|---|---|---|
| Width | Band Width [μm] | Irradiance | | Error Range |
| UV B | 0.28~0.32 | 5 | W/m² | ±35% |
| UV A | 0.32~0.40 | 63 | W/m² | ±25% |
| Visible Light | 0.40~0.52 | 200 | W/m² | ±10% |
| | 0.52~0.64 | 186 | W/m² | ±10% |
| | 0.64~0.78 | 174 | W/m² | ±10% |
| IR | 0.78~3.00 | 492 | W/m² | ±20% |

In Table 1, the term UV B denotes ultraviolet B light, UV A denotes ultraviolet A light and the term “IR” denotes infrared light. When a display device includes the coating window DWP in an embodiment, a difference in yellow index between the light-blocking portion and the exposed portion after the exposure environment test was about 3 or less. This demonstrates a significant improved result compared to a case where in a typical display device, which is manufactured through a manufacturing method not including an operation of providing near-infrared rays and in which a photoinitiator and a photosensitizer remaining in the coating window are each contained in an amount of about 10,000 amu or more, a difference in yellow index between the light-blocking portion and the exposed portion was about 10 or more under the same exposure environment test condition. In an embodiment, the photoinitiator included in window resin may be responsive to ultraviolet light to form free radicals, and the photosensitizer may accelerate such a free radical forming reaction, for example. Accordingly, since the coating window DWP in an embodiment includes substantially small amounts of a photoinitiator and a photosensitizer, or does not include the photoinitiator and the photosensitizer, the free radical formation is minimized, and thus photooxidation caused by the free radicals may be minimized.

That is, since in the coating window DWP in an embodiment, unreacted compounds are decomposed in the exposure environment, an additional reaction of organic materials which form the coating window DWP is induced to minimize decomposition or deformation, thereby alleviating a yellowing phenomenon. Also, in the display device DD of an embodiment including the coating window DWP of this embodiment, unreacted compounds and remaining reaction products are removed. Accordingly, the coating window DWP may prevent the remaining compounds from outgassing and damaging other members, thereby exhibiting excellent reliability.

In addition, the coating window DWP in an embodiment may be formed from a window resin including a polymer resin, a photoinitiator and a photosensitizer, and the photoreaction is performed while the photoinitiator is sufficiently activated due to the photosensitizer. Therefore, the coating window DWP may have a sufficient thickness of about 600 μm and exhibit excellent durability.

The coating window DWP in an embodiment has a pencil hardness of about 9H or more, a bright spot occurrence height of about 11 cm or more, as evaluated with a Dupont impact tester, and an indentation elastic modulus (“EIT”) of about 800 megapascals (MPa) or more, as measured with a nano indenter. The mechanical property of the coating window DWP is similar to a durability of a typical window, and it may be confirmed that the coating window DWP provided in the form of direct coating also exhibits the excellent mechanical property and durability.

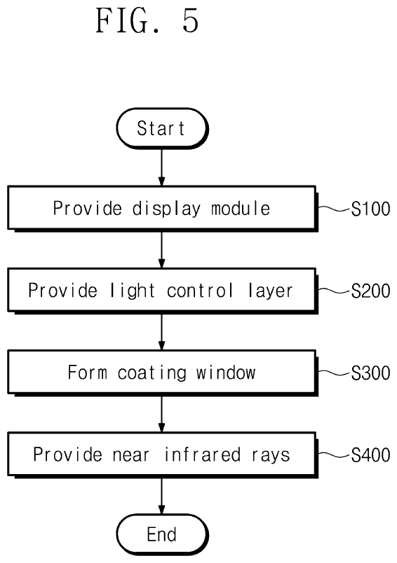

Hereinafter, the description of a method for manufacturing a display device in an embodiment will be made with reference to FIGS. 5 to 7, or the like. In description of the method for manufacturing the display device in an embodiment, etc., the contents duplicated with those described for the display device of the embodiment with reference to FIGS. 1 to 4 will not be explained again and the following description will be mainly focused on the differences.

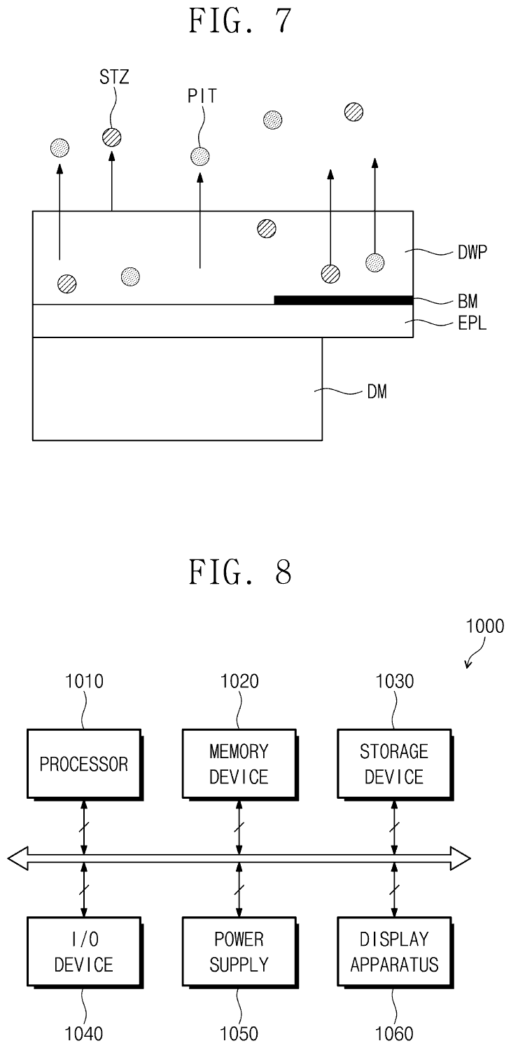

FIG. 5 is a flowchart showing a method for manufacturing a display device of an embodiment. FIGS. 6A to 6E are schematic views respectively illustrating some operations of a method for manufacturing a display device of an embodiment. FIG. 7 is a view schematically illustrating an operation of providing near infrared rays.

Referring to FIG. 5, the method for manufacturing the display device in an embodiment may include operations of: providing a display module (S100), providing a light control layer (S200), and forming a coating window (S300), and providing near infrared rays (S400).

FIG. 6A illustrates the operation of providing the light control layer on the display module (S200). In an embodiment, a light control layer EPL may be a polarization layer. The light control layer EPL may be provided to cover the entirety of the display module DM. The light control layer EPL may be attached to the display module DM using an adhesive layer, or the like. When the light control layer EPL is a polarizing layer, the width of the polarizing layer in one direction may be greater than the width of the display module DM in one direction.

FIG. 6B illustrates an operation of providing a printed layer. A printed layer BM may be provided on the light control layer EPL. The operation of providing the printed layer may be performed between the operation of providing the light control layer (S200) and the operation of forming the coating window (S300). The printed layer BM may be formed by coating and curing an ink resin or the like directly on an upper surface US-PL of the light control layer EPL.

FIGS. 6C and 6D illustrate the operation of forming the coating window (S300). The operation of forming the coating window (S300) may include operations of: providing the window resin directly on the upper surface US-PL of the light control layer, and curing the provided window resin using ultraviolet rays.

FIG. 6C illustrates the operation of providing the window resin, and FIG. 6D illustrates the operation of curing the window resin using ultraviolet rays.

A window resin R-WP may include a polymer resin, a photoinitiator, and a photosensitizer. In an embodiment, the window resin R-WP may be a solvent-free type resin which does not include an organic solvent. The solvent-free type window resin R-WP may be coated to have a sufficient thickness due to relatively low flowability.

The polymer resin included in the window resin R-WP may be a transparent insulating material having relatively high light transmittance in a visible light region. The photoinitiator is reacted by being activated in response to ultraviolet rays, and the photosensitizer may accelerate the degree of activation of the photoinitiator. In an embodiment, the polymer resin may include a silsesquioxane resin, for example. Specifically, the polymer resin may include an epoxy-based silsesquioxane resin.

Also, in an embodiment, the photoinitiator may be an iodonium salt, and the photosensitizer may be ITX. However, the inventive concept is not limited thereto, and the photoinitiator and the photosensitizer may use any material without a limitation as long as the material is easily extractable and removable at a process temperature of about 80° C. or lower when near infrared rays are provided.

The window resin R-WP may be provided to be coated directly on the light control layer EPL. The window resin R-WP may be coated using the light control layer EPL as a base substrate. FIG. 6C illustrates that the window resin R-WP is provided via a nozzle NZ, but the inventive concept is not limited thereto. Any apparatus may be used without a limitation as long as capable of providing the window resin R-WP to a predetermined thickness. In an embodiment, the window resin R-WP may be provided through roll coating, silk screen coating, spray coating, slit coating, or the like, for example.

A coating layer which is a preliminary window P-DWP may be formed by coating the window resin R-WP to a predetermined thickness. The coating window DWP may be formed by irradiating the preliminary window P-DWP with ultraviolet rays EB and curing the window resin R-WP through a photoreaction. The preliminary window P-DWP may be provided to have an area corresponding to the planar area of the light control layer EPL. The edge of the preliminary window P-DWP may overlap the edge of the light control layer EPL.

The window resin R-WP includes both the photoinitiator and the photosensitizer, and thus a photoinitiation reaction and a photocuring reaction may be efficiently carried out in the entirety of the region of the preliminary window P-DWP.

The coating window DWP formed by being irradiated with the ultraviolet rays EB may have a curing rate of about 90% or more. The curing rate in the entirety of the region of the coating window DWP may be about 90% or more. In this specification, the curing rate was evaluated using Fourier-transform infrared spectroscopy (“FT-IR”). The curing rate was evaluated based on the change in the content of each of photoinitiator and photosensitizer before and after being cured using FT-IR.

FIG. 6E illustrates the operation of providing the near infrared rays (S400). After curing the preliminary window P-DWP to form the coating window DWP, near infrared rays NIR may be provided on the coating window DWP. The operation of providing the near infrared rays (S400) may include an operation of performing near infrared ray (NIR) drying. Unreacted compounds remaining in the coating window DWP and reaction residues may be removed by providing the near infrared rays NIR to the coating window DWP.

The coating window DWP may have a light transmittance of about 30% or more in a wavelength range of about 750 nm to about 1000 nm. Accordingly, the near infrared rays NIR are effectively provided in the entirety of the region of the coating window DWP, and thus the unreacted compounds and reaction residues may be easily removed.

FIG. 7 is a view schematically illustrating a state of an operation of providing the near infrared rays of FIG. 6E. When the near infrared rays are provided, a photoinitiator PIT and a photosensitizer STZ remaining in a coating window DWP may be removed. The operation of providing the near infrared rays (S400) may include an operation of removing the photoinitiator PIT and the photosensitizer STZ remaining in the coating window DWP which is formed after the operation of curing the window resin.

Under the condition of providing the near infrared rays NIR, the photoinitiator PIT and the photosensitizer STZ used for forming the coating window DWP may be easily removed from the coating window DWP at a process temperature of about 80° C. or less. That is, when the near infrared rays NIR are not provided, the relatively high temperature condition of about 100° C. or more is desired to remove compounds such as the photoinitiator PIT and the photosensitizer STZ. However, the near infrared rays NIR may accelerate a volatilization reaction, etc., of compounds, and thus the remaining compounds may be easily removed even at a relatively low temperature of about 80° C. or less. Therefore, when the near infrared rays NIR are provided to a display device in which the coating window DWP is formed, the remaining compounds may be effectively removed without thermal damage to the display module DM, or the like.

Table 2 below shows the results of analyzing the content of each of the photoinitiator and the photosensitizer in the coating window before and after the operation of providing the near infrared rays. The contents in Table 2 are the results measured through GC-MS.

TABLE 2

| | Content of Photoinitiator | Content of Photosensitizer |
|---|---|---|
| Classification | (amu) | (amu) |
| Before irradiated | 63831 | 42865 |
| with near infrared | | |
| rays | | |
| After irradiated | 0 | 0 |
| with near infrared | | |
| rays | | |

Referring to the results in Table 2, it may be confirmed that the photoinitiator and the photosensitizer included in the coating window were effectively removed after providing the near infrared rays. Table 3 below shows the change in the content of each of the photoinitiator and the photosensitizer when the near infrared rays are provided to the window resin before forming the coating window through photocuring, and Table 4 below shows a comparison of curing rates in Embodiment and Comparative Example.

The content of each of the photoinitiator and the photosensitizer in Table 3 was measured through GC-MS. Embodiment in Table 4 represents the coating window of the inventive concept, which was manufactured by forming the coating window by photocuring the window resin, and then providing the near infrared rays. Additionally, in Comparative Example, the coating window was formed by providing the near infrared rays to the window resin, and then curing the resin. Comparative Example in Table 4 represents the coating window manufactured by forming the window resin in which the photoinitiator and the photosensitizer are removed under the condition in Table 3. The curing rate in Table 4 was evaluated using FT-IR.

TABLE 3

| | Change in Content within Window resin | |
|---|---|---|
| | Content of | Content of |
| Classification | Photoinitiator (amu) | Photosensitizer (amu) |
| Before irradiated with | 536891 | 378569 |
| near infrared rays | | |
| After irradiated | 1295 | 2465 |
| with near infrared | | |
| rays | | |

TABLE 4

Curing rate (%)

| Classification | Embodiment | Comparative Example |
|---|---|---|
| Front Surface of | 93.5 | 8.9 |
| Coating Window | | |
| Rear Surface of | 90.2 | 3.7 |
| Coating Window | | |

Referring to Table 3, it may be seen that when the near infrared rays are provided not to the cured coating window but to the window resin, the content of each of the photoinitiator and the photosensitizer in the window resin decreases. Therefore, it is shown that the coating window, of Comparative Example in Table 4, which is formed from the window resin under the condition of Table 3 has a significantly low curing rate. It may be confirmed that the coating window manufactured through the operations of the method for manufacturing the display device of the inventive concept has a relatively high curing rate of about 90% or more on both the front and rear surfaces thereof. Referring to the results of Tables 2 to 4, the method includes photocuring the resin for manufacturing the display device in an embodiment, and then providing near infrared rays to the formed coating window, thereby making it possible to minimize the remaining photoinitiator and photosensitizer to be minimized while the coating window has a relatively high curing rate.

FIG. 8 is a block diagram illustrating an electronic device according to an embodiment.

Referring to FIG. 8, in an embodiment, an electronic device 1000 may include a processor 1010, a memory device 1020, a storage device 1030, an input/output (“I/O”) device 1040, a power supply 1050, and a display device 1060. Here, the electronic device 1000 may correspond to the display device DD of FIG. 1. The electronic device 1000 may further include a plurality of ports for communicating with a video card, a sound card, a memory card, a universal serial bus (“USB”) device, or the like. In an embodiment, the electronic device 1000 may be implemented as a television. In another embodiment, the electronic device 1000 may be implemented as a smart phone. However, embodiments are not limited thereto, in another embodiment, the electronic device 1000 may be implemented as a cellular phone, a video phone, a smart pad, a smart watch, a tablet PC, a car navigation system, a computer monitor, a laptop, a head disposed (e.g., mounted) display (“HMD”), or the like.

The processor 1010 may perform various computing functions. In an embodiment, the processor 1010 may be a microprocessor, a central processing unit (“CPU”), an application processor (“AP”), or the like. The processor 1010 may be coupled to other components via an address bus, a control bus, a data bus, or the like. In an embodiment, the processor 1010 may be coupled to an extended bus such as a peripheral component interconnection (“PCI”) bus.

The memory device 1020 may store data for operations of the electronic device 1000. In an embodiment, the memory device 1020 may include at least one non-volatile memory device such as an erasable programmable read-only memory (“EPROM”) device, an electrically erasable programmable read-only memory (“EEPROM”) device, a flash memory device, a phase change random access memory (“PRAM”) device, a resistance random access memory (“RRAM”) device, a nano floating gate memory (“NFGM”) device, a polymer random access memory (“PoRAM”) device, a magnetic random access memory (“MRAM”) device, a ferroelectric random access memory (“FRAM”) device, or the like, and/or at least one volatile memory device such as a dynamic random access memory (“DRAM”) device, a static random access memory (“SRAM”) device, a mobile DRAM device, or the like.

In an embodiment, the storage device 1030 may include a solid state drive (“SSD”) device, a hard disk drive (“HDD”) device, a CD-ROM device, or the like. In an embodiment, the I/O device 1040 may include an input device such as a keyboard, a keypad, a mouse device, a touchpad, a touch-screen, or the like, and an output device such as a printer, a speaker, or the like.

The power supply 1050 may provide power for operations of the electronic device 1000. The power supply 1050 may provide power to the display device 1060. The display device 1060 may be coupled to other components via the buses or other communication links. In an embodiment, the display device 1060 may be included in the I/O device 1040.

A display device of an embodiment is disposed on a display module and includes a coating window formed from a window resin. The coating window includes or consists of only a photoinitiator and a photosensitizer each in an amount of less than about 10,000 amu, no yellowing phenomenon may occur even when exposed to external light, and thus the display device may exhibit the excellent reliability.

Additionally, since a method for manufacturing a display device of an embodiment includes an operation of providing near infrared rays to a coating window after forming the coating window from a window resin, the coating window is cured to have a sufficient curing rate and ensure excellent mechanical property, and unreacted compounds remaining in the coating window are minimized, thereby providing a display device with excellent reliability.

A display device in an embodiment may include a coating window including or consisting of a substantially small amount of a photoinitiator and a photosensitizer, thereby exhibiting the improved reliability in which yellowing is minimized and the excellent optical property is maintained even when exposed to external light.

Also, a method for manufacturing a display device in an embodiment may include providing near infrared rays after forming a coating window, and thus easily remove unreacted compounds using the near infrared rays, whereby the method may be used for manufacturing a display device with the excellent reliability.

Although the embodiments of the inventive concept have been described, it is understood that the inventive concept should not be limited to these embodiments but various changes and modifications may be made by one ordinary skilled in the art within the spirit and scope of the inventive concept as hereinafter claimed. Therefore, the technical scope of the inventive concept is not limited to the contents described in the detailed description of the specification, but should be determined by the claims.

What is claimed is:

1. A display device comprising:
a display module;
a light control layer disposed on the display module; and
a coating window disposed directly on an upper surface of the light control layer and formed from a window resin including a polymer resin, a photoinitiator, and a photosensitizer,
wherein a content of each of the photoinitiator and the photosensitizer included in the coating window is less than about 10,000 atomic mass unit, and the content is measured through gas chromatography-mass spectrometry.

2. The display device of claim 1, wherein the polymer resin comprises a silsesquioxane resin.

3. The display device of claim 1, wherein the photoinitiator is an iodonium salt, and the photosensitizer is isopropylthioxanthone (ITX).

4. The display device of claim 1, wherein the coating window has a thickness of about 600 micrometers or more.

5. The display device of claim 1, wherein the coating window has a light transmittance of about 30% or more in a wavelength range of about 750 nanometers to about 1000 nanometers.

6. The display device of claim 1, wherein the coating window has, in a visible light range, a transmittance of about 90% or more and a yellow index of about 1 or less.

7. The display device of claim 1, wherein the coating window is a single layer.

8. The display device of claim 1, further comprising a printed layer disposed directly between the light control layer and the coating window,
wherein the printed layer includes a portion non-overlapping the display module.

9. The display device of claim 1, wherein the coating window overlaps an entirety of the display module, and in a plan view, an area of the coating window is greater than an area of an upper surface of the display module.

10. The display device of claim 1, wherein the light control layer is a polarization layer, and
an edge of the polarization layer overlaps an edge of the coating window.

11. A method for manufacturing a display device, the method comprising:
providing a display module;
providing a light control layer on the display module;
forming a coating window directly on an upper surface of the light control layer; and
providing near infrared rays to the coating window.

12. The method of claim 11, wherein the forming the coating window comprises:
providing directly, on the upper surface of the light control layer, a window resin including a polymer resin, a photoinitiator, and a photosensitizer; and
curing the window resin using ultraviolet rays.

13. The method of claim 12, wherein a content of each of the photoinitiator and the photosensitizer, after the providing the near infrared rays, is less than about 10,000 atomic mass unit, and the content is measured through gas chromatography-mass spectrometry.

14. The method of claim 12, wherein the providing the near infrared rays comprises removing the photoinitiator and the photosensitizer remaining in the coating window after the curing the window resin.

15. The method of claim 12, wherein the photoinitiator is an iodonium salt, and the photosensitizer is isopropylthioxanthone (ITX).

16. The method of claim 12, wherein the polymer resin comprises a silsesquioxane resin.

17. The method of claim 12, wherein the coating window, after the curing the window resin, has a curing rate of about 90% or more.

18. The method of claim 11, wherein a process temperature in the providing the near infrared rays is about 40 degrees Celsius or more to about 80 degrees Celsius or less.

19. The method of claim 11, wherein the coating window has a light transmittance of about 30% or more in a wavelength range of about 750 nanometers to about 1000 nanometers.

20. The method of claim 11, wherein in the forming the coating window, an edge of the coating window overlaps an edge of the light control layer, and
the edge of the light control layer further protrudes outwards than an edge of the display module.

21. An electronic device comprising:
a display module;
a light control layer disposed on the display module; and
a coating window disposed directly on an upper surface of the light control layer and formed from a window resin including a polymer resin, a photoinitiator, and a photosensitizer,
wherein a content of each of the photoinitiator and the photosensitizer included in the coating window is less than about 10,000 atomic mass unit, and the content is measured through gas chromatography-mass spectrometry.
